(19) United States
(12) Patent Application Publication
(10) Pub. No.: US 2013/0162120 A1
(43) Pub. Date: Jun. 27, 2013

(54) Outdoor Television Display System

(71) Applicants: Michael A. Campagna, Plainfield, IL (US); Jack Mckeague, Orland Park, IL (US); Donald Lee Anderson, Oak Park, IL (US)

(72) Inventors: Michael A. Campagna, Plainfield, IL (US); Jack Mckeague, Orland Park, IL (US); Donald Lee Anderson, Oak Park, IL (US)

(73) Assignee: Ciil Technologies, LLC

(21) Appl. No.: 13/337,519

(22) Filed: Dec. 27, 2011

(51) Int. Cl. H05K 5/02; B23P 11/00

(52) U.S. Cl. 312/223.1; 29/428

(57) ABSTRACT

An enclosure for enclosing a flat panel display for viewing that is substantially sealed and resistant to liquid ingress. The enclosure comprises a bezel, a substantially transparent front cover, and a rear cover. The bezel defines a perimeter surface defining an enclosure area having a display opening and a rear opening and includes an assembly of a plurality of frame members having beveled ends. The substantially transparent front cover is operatively connected to the bezel and covers the display opening. The rear cover assembly is operatively connected to the bezel and covers the rear opening.

### FIELD OF THE INVENTION

The present invention relates generally to structures for enclosing display devices. More particularly, the present invention relates to enclosures for protecting flat-panel display devices from ambient conditions encountered in a viewing location.

### BACKGROUND

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

In recent years, flat panel televisions have become enormously popular in both commercial and residential sectors. As the prices for plasma and liquid crystal display (LCD) flat panel displays have continued to fall, and the quality for the same devices have improved, more and more businesses and individuals have purchased such devices for both home and business purposes.

The advantages of flat panel displays has also led to expanded application and placement of display devices, including locating display devices in new and challenging and environments. For example, display devices might be located outdoors in various residential and commercial settings for entertainment or marketing purposes, potentially exposing the display device to damaging rain, snow, debris, and other elements. Display devices might also be located in indoor environments such as restrooms, kitchens, and industrial settings for various entertainment, marketing, and informational purposes. As with outdoor applications, liquids and other potential contaminants may be near or come into contact with the mounted display device, potentially damaging or degrading the performance of the display device. It is desirable to protect the display device, which is often quite expensive, from exposure to environmental and other potential contaminants. Accordingly, various, sometimes bulky, environmental enclosures have been developed that are intended to protect a display device from the elements and other containments to permit locating such displays outdoors and in other potentially inhospitable environments.

### SUMMARY

In one embodiment, an enclosure for enclosing a flat panel display that is substantially sealed and resistant to liquid ingress is disclosed. The enclosure comprises a bezel, a substantially transparent front cover, and a rear cover. The bezel defines a perimeter surface defining an enclosure area having a display opening and a rear opening and includes an assembly of a plurality of frame members having beveled ends. The substantially transparent front cover is operatively connected to the bezel and covers the display opening. The rear cover assembly is operatively connected to the bezel and covers the rear opening.

In another embodiment, a method of preparing a substantially sealed enclosure that is impervious to ingress of liquid for enclosing a flat panel display device is disclosed. The method comprises assembling a bezel by joining beveled ends of a plurality of frame members to each other so as to form a rectangle. The bezel is characterized by a display opening, a rear opening, and an outer peripheral surface of the enclosure. The method further comprises attaching a rear cover, covering at least a portion of the rear opening. The method further comprises placing a flat panel display device within the enclosure through the display opening and coupling the flat panel display device to the bezel, the flat panel display device including a display area viewable through the front cover. The method further comprises attaching a front cover to the bezel, the front cover covering the display opening.

In yet another embodiment, an enclosure for enclosing a flat panel display that is substantially sealed and resistant to liquid ingress is disclosed. The enclosure comprises a bezel, a substantially transparent front cover, and a rear cover assembly. The bezel defines a front opening and a rear opening and comprises a plurality of frame members, each of the plurality of frame members having an outer surface and an inner edge, the outer surface being longer than the inner edge, the plurality of frame members joined to each other at a plurality of mitered joints formed by angled ends at the end of each of the plurality of frame members. The substantially transparent front cover is operatively connected to the bezel and covers the display opening. The rear cover assembly is operatively connected to the bezel and covers the rear opening.

These and other features, together with the organization and manner of operation thereof, will become apparent from the following detailed description when taken in conjunction with the accompanying drawings, wherein like elements have like numerals throughout the several drawings described below.

### BRIEF DESCRIPTION OF THE DRAWINGS

FIG. 1 is a front plan view of a bezel in accordance with an exemplary embodiment, FIG. 1A is a front plan view of a call-out of a corner of the bezel of FIG. 1, and FIG. 1B is a perspective view of a call-out of a corner of the bezel of FIG. 1;

FIG. 2 is a rear plan view of the bezel of FIG. 1, FIG. 2A is a rear plan view of a call-out of a corner of the bezel of FIG. 2, and FIG. 2B is a perspective view of a call-out of a corner of the bezel of FIG. 2;

FIG. 3 is a front perspective view of the bezel of FIG. 1;

FIG. 4 is a rear perspective view of the bezel of FIG. 1;

FIG. 5 is a front plan view of an enclosed display device constructed in accordance with an exemplary embodiment, FIG. 5A is a cross-section view of FIG. 5 taken at line 5A-5A, FIG. 5B is a call-out of the enclosed display device of FIG. 5A, and FIG. 5C is an exploded view of the enclosed display device of FIG. 5 taken at line 5A-5A;

FIG. 6 is a front plan view of the front cover of the enclosed display device of FIG. 5;

FIG. 7 is a cross-section showing a portion of the bezel and the front cover of the enclosed display device of FIG. 5;

FIG. 8A is a perspective view of the rear cover assembly of FIG. 5, and FIG. 8B is an exploded view of the rear cover assembly of FIG. 5;

FIG. 9A is a cross-section showing a portion of the display device, a portion of the rear cover assembly, and the heat pipe assembly of the enclosed display device of FIG. 5, and FIG. 9B is a perspective view showing the heat pipe assembly of FIG. 9A, and

FIG. 10 is a schematic illustrating components of the enclosed display device of FIG. 5.

### DETAILED DESCRIPTION OF VARIOUS EMBODIMENTS

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

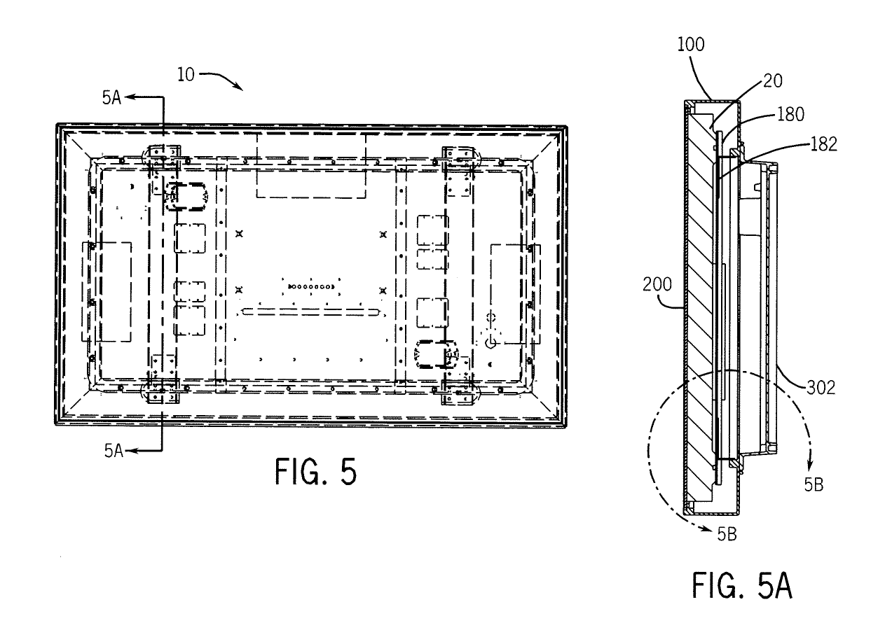

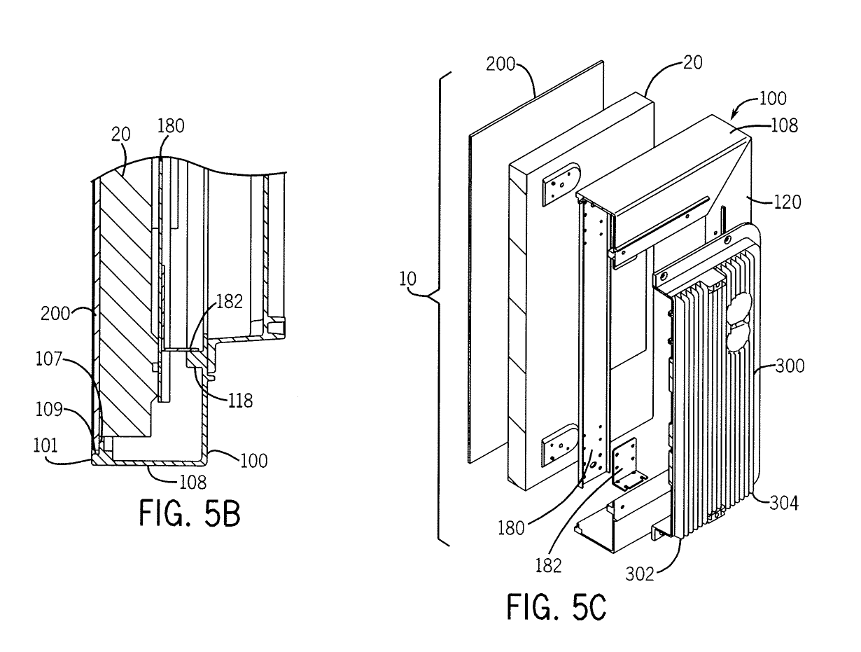

FIGS. 5A-C illustrate a display enclosure 10 constructed in accordance with an embodiment of the present invention. The display enclosure 10 is a protective enclosure configured to enclose a display device 20 such as a plasma, LCD, or LED flat panel display device 20. The display enclosure 10 comprises a bezel 100 that defines a frame disposed about the periphery of the display device 20. A front cover 200, or display cover, is coupled to the bezel 100 and covers a display opening 111, or front opening, defined by the bezel 100. The front cover 200 comprises a substantially transparent material that permits viewing of the display device 20 within the display enclosure 10. The display enclosure 10 further comprises a rear cover assembly 300 coupled to the bezel 100. The rear cover assembly 300 covers a rear opening 311 substantially opposite the display opening 111 defined by the bezel 100. The rear cover assembly 300 may include a heat sink portion 302 and a cable entry portion 350 that permits passage of various power, video, audio, and other data carrying cables.

The display enclosure 10 is constructed so that the display device 20 may be located in an outdoor viewing environment or in other environments where the display device 20 requires or may benefit from protection from ambient conditions. Accordingly, the display enclosure 10 is constructed to resist and substantially prevent ingress of various liquids that may be encountered in the viewing location, including precipitation when the display enclosure 10 is mounted for outdoor viewing of the display device 20. In various embodiments, the display enclosure 10 is constructed to prevent ingress of rain, snow, splashing liquid, and various atmospheric particulates. In a particular embodiment, the display enclosure 10 is constructed to prevent ingress of liquid at a submersed depth of up to five feet of water, which may correspond to a modified rating of the IP68 standard (the contents of which are incorporated herein by reference).

As described in detail below, the display enclosure 10 may be provided with features that enable or enhance performance and operation under various ambient conditions, while protecting the display device 20 from adverse conditions such as liquids and/or various particulates present in the atmosphere that may come into contact with the display enclosure 10. The bezel 100, for example, may be constructed to provide the display enclosure 10 with a narrow periphery, or a low profile, that closely surrounds the display opening 111 through which the display area of the display device 20 is visible. Thus, the outer periphery of the bezel 100 defines an enclosure area and the display opening 111 defines a display opening area. In this configuration, the distance between an inner edge of the bezel 100 and the periphery of the bezel 100, the bezel thickness, is minimized. In a particular embodiment, the bezel thickness is less than about 50 mm, and in a further embodiment, the bezel thickness is less than about 25 mm. In further embodiments, the bezel thickness may fall between about 25 mm and about 50 mm.

The low profile of the bezel 100 permits the display area of the display device 20 to closely approach the periphery of the bezel 100. For example, the display opening area is maximized relative to the enclosure area. In a particular embodiment, the display opening area is at least about 85 percent of the enclosure area, and in another embodiment, the display area opening is at least about 92 percent of the enclosure area. In further embodiments, the display opening area may fall between about 85 percent and about 92 percent of the enclosure area. The above described configurations offer a clean, low profile look where the edge of the display area of the display device 20 is in proximity to the periphery of the display enclosure 10. These configurations permit, for example, a plurality of enclosures 10, each with a display device 20, to be arranged in a video wall such that the respective display devices 20 are in close proximity to one another, thereby enhancing the presentation of the image or images displayed on the display devices 20.

The display enclosure 10 may also include thermal modulation features. Such thermal modulation features may be active and/or passive and provide temperature control within the display enclosure 10 to assist in maintaining an internal temperature within the display enclosure 10 that is within an operating range of the display device 20. Still further, the display enclosure 10 may include various additional features that, for example, sense ambient light conditions and communicate with the display device 20 to adjust the brightness of the display to enhance viewability of the display device 20 under various light conditions.

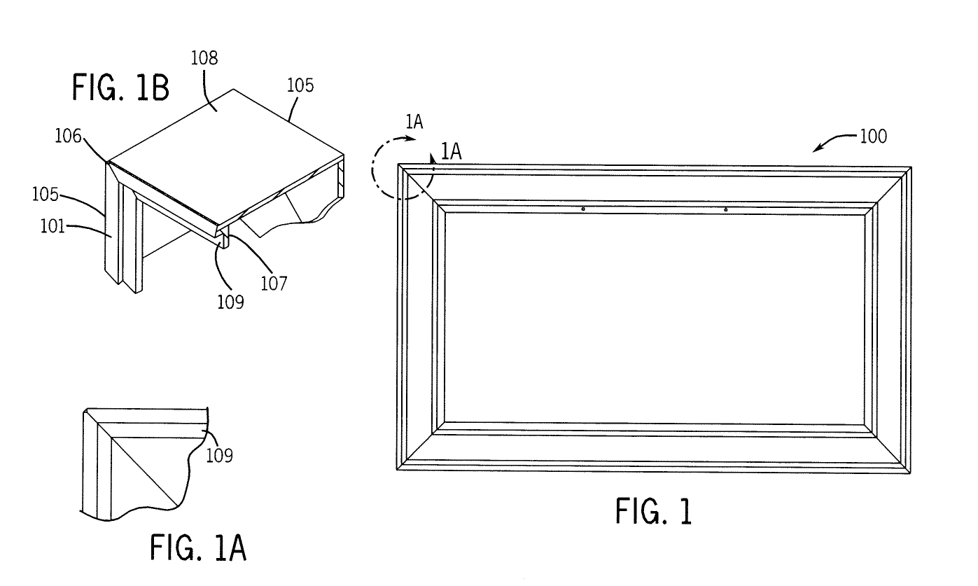

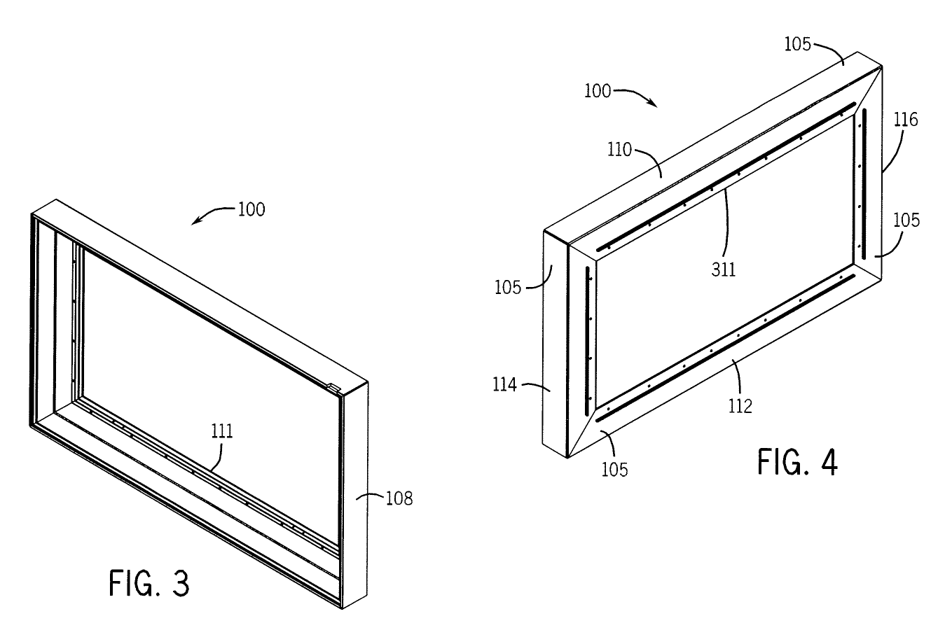

With reference to FIGS. 1-5, the bezel 100 defines the periphery of the display enclosure 10. The bezel 100 is generally sized such that the display device 20 fits within the region defined by the bezel 100. The bezel 100 may comprise a plurality of frame members 105 that are assembled to define the bezel 100. The plurality of frame members 105 may be constructed of metal such as aluminum or other material capable of providing sufficient strength and rigidity, while maintaining a low peripheral profile for the display enclosure 10. In the embodiment depicted in FIG. 1-5, the bezel 100 comprises four frame members 105 each comprising an elongated structure having a generally “L-shaped” cross-section. The frame members 105 include an upper frame 110, a lower frame 112, a first lateral frame 114, and a second lateral frame 116. While the depicted embodiment includes four frame members 105, other configurations of the bezel 100 may be constructed, including a single-piece frame, two-piece frame, and frames comprising three or more pieces.

As illustrated in FIGS. 1B, 5B, and 5C, the frame members have a modified “L-shape” cross-section. Referring to FIG. 5B, the frame members 105 may include an inner edge 107 along a bezel front surface 101 that extends inward away from the outer surface of the bezel 108 and set back from the bezel front surface 101. The inner edge 107 forms a front cover ledge 109 that is configured to accept the periphery of the front cover 200. The inner edge 107 defines the display opening 111. The frame members 105 may also include a connecting bracket rib 118 configured for coupling to a connecting bracket 182, as described in further detail below. The ends of each of the frame members 105 are cut at an angle or beveled, forming a miter 106 so that, when the ends of two frame members 105 are abutted, an angle of approximately 90 degrees is formed. In a particular embodiment, the end of each of the frame members 105 is approximately 45 degrees. However, in other embodiments, the ends may include complimentary angles, such that when adjacent ends are abutted a substantially right angle is formed. One benefit of the depicted frame members 105 having ends that are cut at an angle or beveled, forming a miter 106, is ease of assembly. In particular, the beveled ends permit the plurality of frame members 105 to be easily assembled into a bezel 100 being rectangular in shape (i.e. having right-angle corners).

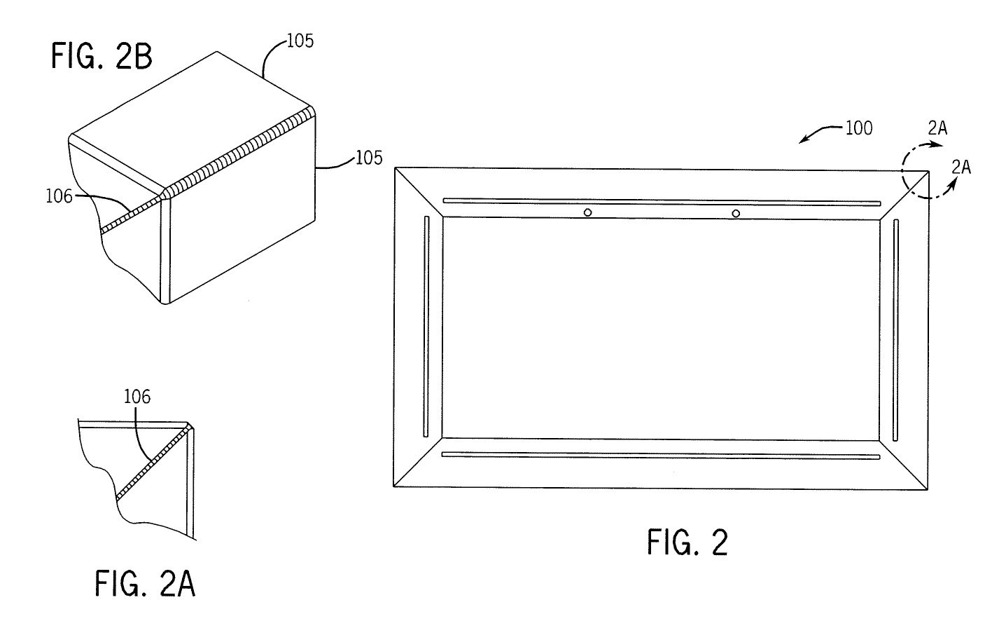

As depicted in FIGS. 1-4, the plurality of frame members 105 are assembled to form the perimeter of the bezel 100, defining an outer or peripheral surface 108. The plurality of frame members 105 may be joined by welding. In particular, as illustrated in FIGS. 2A and 2B, the mitered ends of two frame members 105 are brought into proximity of one another or abutted and welded together. In a particular embodiment, the weld bead is formed on the bezel front surface 101, the bezel outer surface 108, and the bezel rear surface 120, not inside the bezel 100, and is ground down so that it does not protrude from either the bezel front surface 101, the bezel outer surface 108, or the bezel rear surface 120. While the depicted embodiment of the bezel has been described as being assembled via welding, other techniques for joining the frame members 105 may also be used, including adhesives, connecting elements, and combinations thereof Regardless of the specific construction of the bezel 100, it will be appreciated that, in use, the bezel 100 provides support for the display device 20 and is substantially impervious to liquids and prevents ingress of liquids and other containments into the display enclosure 10 that may be encountered in the mounting environment.

Once the plurality of frame members 105 are joined to form the perimeter of the bezel 100, the bezel 100 may undergo a treatment or plurality of treatments. These treatments can include, for example, applying an organic coating and/or sealant to the bezel 100, which may be utilized to enhance resistance to environmental effects, strengthen the bezel, and/or provide a decorative coating. Various treatments can include polyurea coatings, urethane coatings, polyurethane coatings, epoxy coatings, powder coating, painting, anodizing, and combinations thereof. The material utilized in a particular treatment may be characterized as being adherable to the bezel 100 or an intermediate material disposed on the bezel and durable under various environmental conditions. Additionally, it may be desirable for the treatment to be characterized by one or more cosmetic attributes such as an ability to conceal surface imperfections in the bezel 100, including seams between the frame members 105, as well as providing a color, texture, and finish suitable for an outdoor display enclosure.

In an embodiment, the bezel 100 is treated with a polyurea coating. The polyurea coating may be applied as a liquid to portions of the bezel 100, such as the external surfaces or selected surfaces, or may be applied to the entire bezel 100. Selected surfaces of the bezel 100 may be coated by masking or other techniques. Application of the polyurea coating may be accomplished by a spray process. In various embodiments, the polyurea coating comprises a two-component system that includes a catalyst to effectuate curing of the polyurea on the bezel 100 at room temperature and without the need for a subsequent heat treating operation. In a particular embodiment, the two-component polyurea has the product designation UL XT 66 and is available from Ultimate Linings, LTD, of Houston, Tex. After curing, the polyurea coating provides a weatherproof seal or surface over the applied portions of the bezel.

Various processes may be used to apply the organic coating to the bezel 100, including by pumping the material to a spraying device. Proportioning valves achieve the desired ratio of the two-components, which are mixed into a blended flow prior to discharge from the spaying device onto the bezel. Prior to application, the viscosity of the polyurea may lowered by heating the material in order to improve pumping efficiency and spraying. In a particular embodiment, the components of a two-component polyurea system are heated to about 150° F. In a particular embodiment, the components are proportioned and heated using a Reactor™ proportioning and heating system from Graco Inc. of Minneapolis, Minn.

Two-component polyurea provides a highly durable and weatherproof coating over the bezel 100. In addition to durability, the polyurea can provide an aesthetic finish that does not require a subsequent painting or coating step or a post-application heat treatment step to cure the coating. For example, where the bezel 100 includes external seams between the frame members 105, the polyurea coating can be applied and cured to form a surface that effectively conceals the seams to provide a finish with a uniform surface appearance on the bezel 100. The amount of material applied may be varied to achieve the desired thickness of the coating. In a particular embodiment, a finished polyurea coating of about 0.060 inches is utilized. Accordingly, a two-component polyurea system can enhance manufacturability and efficiency relative to conventional multi-step finishing processes.

With reference to FIGS. 1B, 5B, and 7, and as described above, the plurality of frame members 105 may include an inner edge 107 along a bezel front surface 101 that defines the display opening 111. The display area of the display device 20 is visible through the display opening 111. As such, the bezel 100 may be constructed to various dimensions to accommodate display devices 20 of different sizes. For example, the bezel 100 may be constructed in accordance with display device screen sizes that are commonly manufactured. In a particular embodiment, the bezel 100 is constructed to accommodate a 42 inch display device 20. In another particular embodiment, the bezel 100 is constructed to accommodate a 47 inch display device 20.

The bezel 100 is constructed such that the thickness of the bezel, i.e., the perpendicular distance between the inner edge 107 and the peripheral surface 108, the portion visible when viewing the display enclosure 10 from the front, is minimized. That is, the bezel 100 has a low profile surrounding the display opening 111. For example, in a particular embodiment, the distance between inner edge 107 and the peripheral surface 108 of the display enclosure 10 is less than about 25 mm. In other words, the area of the display opening 111 is maximized relative to the area of the display enclosure 10 defined by the peripheral surface 108 of the display enclosure 10. For example, in a particular embodiment, the area of the display opening 111 is at least about 85 percent of the area of the display enclosure 10. In another particular embodiment, the area of the display opening 111 is at least about 92 percent of the area of the display enclosure 10. The low peripheral profile of the bezel 100 may enhance the overall look of the display enclosure 10, as well as minimize the space needed in a mounting location for installation of an enclosed display device 20. In multiple screen arrangements, where several displays are positioned horizontally and/or vertically adjacent one another, the low profile of the bezel 100 may provide an enhanced seamless appearance of the displayed image(s) on the multiple display devices 20.

The display opening 111 is covered by the front cover 200. As shown in FIGS. 1A, 1B, 5B, and 7, the front cover ledge 109 may be disposed along the inner edge 107 and be recessed from the bezel front surface 101 to receive the front cover 200. The front cover ledge 109 may be recessed from the bezel front surface 101 about the thickness of the front cover 200 so that the bezel front surface 101 and the front cover 200 define a substantially smooth surface. In other words, the surface of the front cover 200 is neither perceptibly raised above, nor depressed below the bezel front surface 101. Alternatively, the front cover 200 may extend over the front of the bezel front surface 101 to the outer edge of bezel 100 or a portion thereof. In yet another embodiment, the front cover 200 may be disposed in back of the bezel front surface 101 and received within the bezel 100.

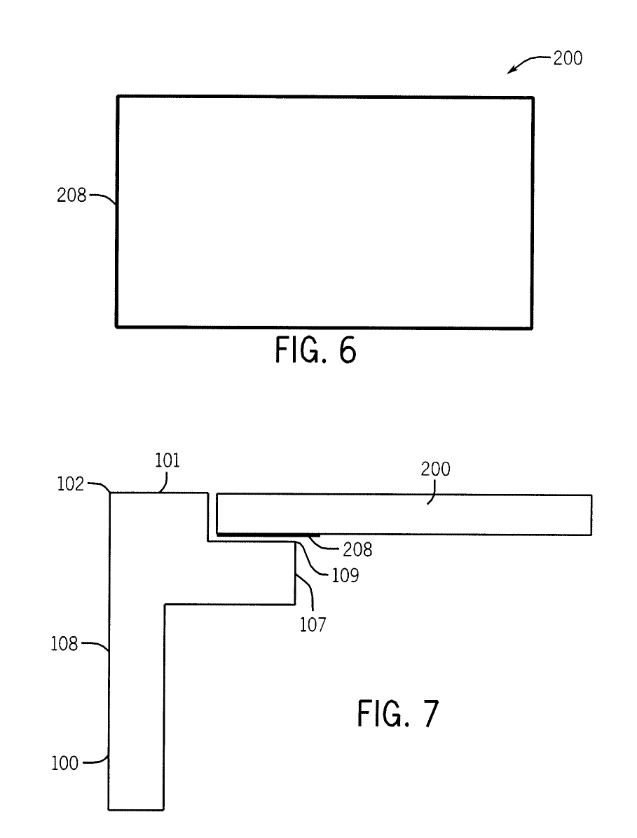

FIGS. 5B, 5C, 6, and 7 show the front cover 200, which attaches to a front portion of the bezel 100. The front cover 200 comprises a plate of a substantially transparent material that permits viewing of the display device 20 within the display enclosure 10. Accordingly, the front cover 200 may comprise glass or a substantially transparent plastic. In a particular embodiment, the front cover 200 comprises tempered glass having a thickness of approximately 4 millimeter, though other thicknesses may be used. The front cover 200 is joined to the bezel 100 in a manner that prevents ingress of liquids into the display enclosure 10. For example, the front cover 200 may be bonded to the bezel 100 using an adhesive such as a urethane adhesive. As shown in FIGS. 6 and 7, the front cover 200 may include a border 208 that may be substantially opaque, on the front and/or rear surfaces about the periphery to mask the bonding region between the front cover 200 and the front cover ledge 109. The front cover 200 may further include an anti-reflective coating on the front and/or rear surfaces to reduce photopic reflection. The front cover 200 may also be treated to mitigate ambient ultraviolet (UV) light degradation of the polarizer module of the display device 20. For example, the front cover 200 may include a UV coating configured to shield the polarizer from at least a portion of ambient UV radiation. In various embodiments, the front cover 200 is of sufficient strength to withstand ambient conditions when the display enclosure 10 is located for outdoor viewing.

The display enclosure 10 may include internal supports disposed within the display enclosure 10. As depicted in FIGS. 5A-C, the display enclosure 10 includes display brackets 180. The display brackets 180 are attachable to a rear portion of the display device 20. The display brackets 180 generally comprise elongated members with openings for receiving connecting elements to secure the display device 20. The display brackets 180 may be directly coupled to the bezel 100 or, as depicted, by connecting brackets 182 attachable to the bezel 100. The display brackets 180 secure the display device 20 in the display enclosure 10 and provide additional rigidity to the display enclosure 10.

In various embodiments, the display enclosure 10 is constructed by assembling the plurality of frame members 105 to form the bezel 100 as described above. As illustrated in FIG. 5A and 5C, the connecting brackets 182 are coupled to the bezel 100 and the display brackets 180 are coupled to the connecting brackets 182. With the connecting brackets 182 and/or the connecting brackets 182 in place, the display device 20 is introduced into the region defined by the bezel 100 through the display opening 111. The display device is then operatively connected to the bezel 100 via the connecting brackets 182 and/or the connecting brackets 182.

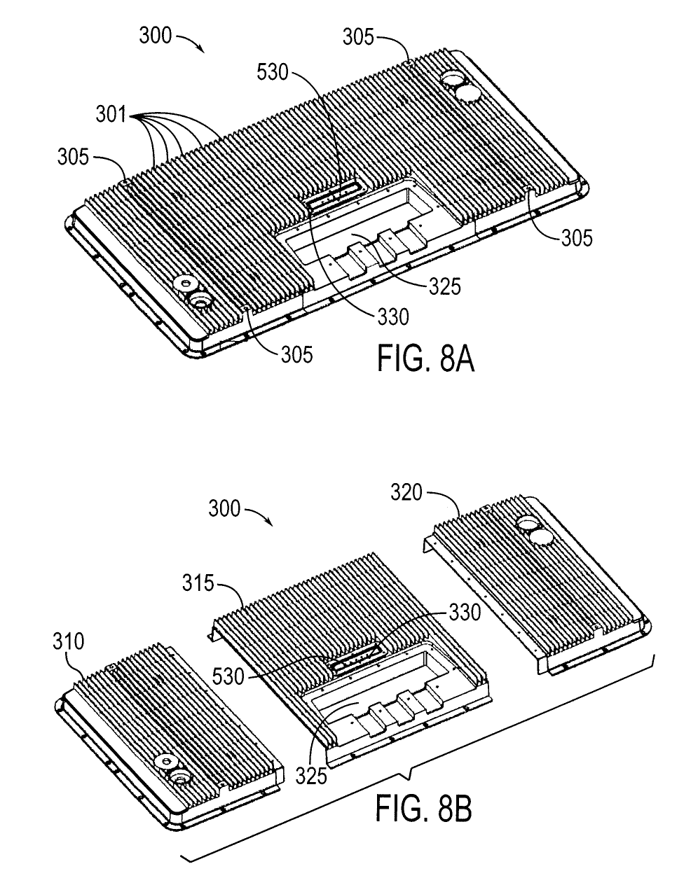

As shown in FIG. 5C, a rear cover assembly 300 covers the rear portion of the display enclosure 10. More particularly, the rear cover assembly 300 covers the rear opening 311 defined by the bezel 100. The rear cover assembly 300 is attached to a rear surface 122 extending from a rear edge 121 of the bezel 100. The rear cover assembly 300 is joined to the bezel 100 in a manner that prevents ingress of liquids into the display enclosure 10. A plurality of connecting elements may be received about the perimeter of the rear cover assembly 300 in order to join the rear cover assembly 300 to the bezel 100. The use of removable connecting elements allows for installation of and access to the display device 20 within in the display enclosure 10. It will be appreciated that the connection of the rear cover assembly 300 to the bezel 100 is configured to prevent ingress of liquid into the display enclosure 10. In an embodiment, a gasket may be disposed between the rear cover assembly 300 and the bezel 100 to provide appropriate sealing of the display enclosure 10. The rear cover assembly 300 also serves as a heat sink, dissipating heat generated from within the display enclosure 10 to the environment outside the enclosure. As such, at least a portion of the rear cover assembly 300 may comprise a material having a relatively high thermal conductivity. For example, in an embodiment, the rear cover assembly 300 comprises die cast aluminum. As depicted in FIGS. 5C, 8A, and 8B, the rear cover assembly 300 assembly may include a heat sink portion that comprises a plurality of fins 304 disposed on the outer surface to enhance convective transfer of heat generated from within the display enclosure 10 to the environment.

FIG. 8B shows an embodiment of the rear cover assembly 300 that comprises a plurality of panels, including a left panel 310, a central panel 315, and a right panel 320, that are coupled together. Similar to the bezel 100, the left panel 310, the central panel 315, and the right panel 320 may be joined using a high-strength adhesive such as epoxy but may be attached using other techniques, including connecting elements, welding, and combinations thereof As shown in FIGS. 8A and 8B, the rear cover assembly 300 may include a plurality of mount attachment features 305 that permit the display enclosure 10 to be coupled to a pedestal, wall mount, ceiling mount, or other mounting system. In an embodiment, the plurality of mount attachment features 305 comprises openings disposed in the rear cover assembly according to an industry standard pattern. The rear cover assembly 300 may include an access area 325 as shown in FIGS. 8A and 8B. The access area 325, for example, provides entry for power and signal cables coupled to the display device 20. An access cover (not shown) may be attachable to the rear cover assembly 300 and may include cable glands to seal the cable entries, preventing ingress of liquid into the display enclosure 10 at the cable entry point. The rear cover assembly 300 may include a display control access 330 for an on screen display (OSD) interface 530. The OSD interface 530 may include a number of inputs operable by a user that allow for manual control and/or adjustment of settings of the display device 20. A cable entry cover 335 may be installed over the display control access 330 to prevent ingress of liquids into the display enclosure 10.

Various thermal control devices may be disposed within or at least partially within the display enclosure 10, to assist in maintaining the internal temperature of the display enclosure 10. Thermal control may be accomplished by including devices intended to add and/or remove heat from the display enclosure 10 depending on ambient conditions and/or the operating conduction of the display device 20. The various thermal control devices may work independently or in concert to assist in modulating the temperature inside the display enclosure 10 within the operating temperature range and/or storage temperature range of the display device 20 under various ambient conditions. In a particular embodiment, the display enclosure 10 is capable of maintaining the internal temperature inside the enclosure within the operating range of the display device 20 for an ambient temperature range of between about 1 degrees Celsius and about 60 degrees Celsius. The thermal control devices within the display enclosure 10 may comprise passive and/or active devices.

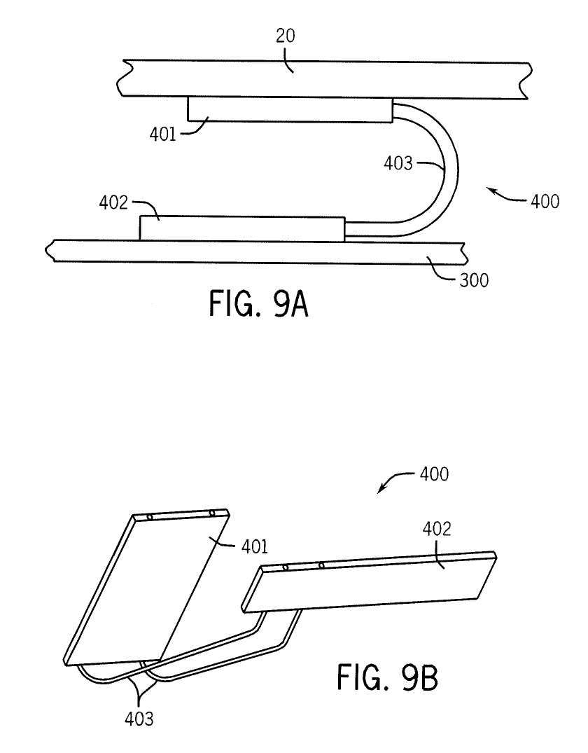

One of the thermal control devices within the display enclosure 10 may comprise a heat pipe assembly 400. The display enclosure 10 may include a plurality of heat pipe assemblies 400. With reference to FIG. 9A, the heat pipe assembly 400 is coupled to the display device 20 and the rear cover assembly 300. The heat pipe assembly 400 conducts heat generated by the display device 20 to the rear cover assembly 300, which as described above, may comprise a material of relatively high thermal conductivity as well as a plurality of fins 304 for dissipating heat from the display enclosure 10 to the environment. The heat pipe assembly 400 comprises a thermal connecting element 402 that thermally couples a display device heat spreader 401 and a rear cover heat spreader 403. The display device heat spreader 401 may be directly or operatively coupled to a rear portion of the display device 20. The rear cover heat spreader 403 is directly or operatively coupled to the rear cover assembly 300. Heat generated by the display device 20 is consequently conducted via the heat pipe assembly 400 to the rear cover assembly 300. It will be appreciated that the effectiveness of the heat pipe assembly 400 to achieve temperature control within the display enclosure 10 will depend on the area of the interfaces, quality of the interfaces, and location of the display device heat spreader 401 in relation to the display device 20 and the heat generating portions thereof.

The display enclosure 10 may also include an internal fan 410 located within the display enclosure 10. The internal fan 410 circulates air within the display enclosure 10, mitigating thermal gradients or hot spots on, for example, a surface of the display device 20 and regions within the display enclosure 10. The internal fan 410 is electrically coupled to a power source to provide operating power. In an embodiment, described more fully below, a power supply 500 may be included within the display enclosure 10 to provide direct or indirect power to the internal fan 410 and other devices within the display enclosure 10. The internal fan 410 may also be electrically coupled to a thermal control unit 510. In an embodiment, the thermal control unit 510 may comprise a thermostat that is capable of detecting a temperature within the display enclosure 10 and/or on the display device 20. In a particular embodiment, a dual temperature integrated circuit sensor is mounted to the thermal control unit 510. The thermal control unit 510 may be equipped with one or more temperature set points. The thermal control unit 510 may activate the internal fan 410 (or other thermal control device) when a first temperature set point is detected, for example, 30 degrees Celsius. The internal fan 410 then operates, mixing the air within the display enclosure 10, for a predetermined period, until the detected internal temperature falls below the first temperature set point, or the thermal control unit 510 otherwise shuts off the internal fan 410.

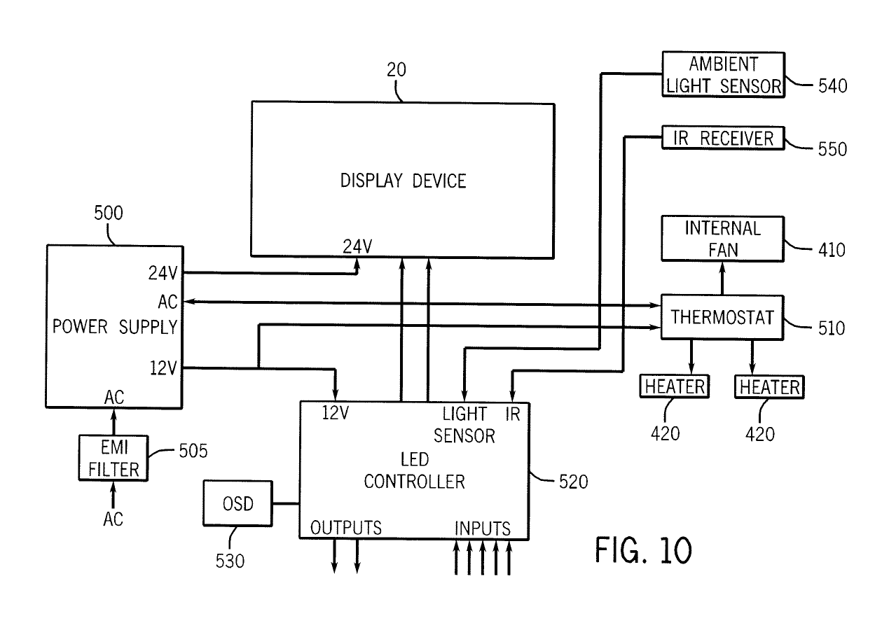

With reference to FIG. 10, a heating element 420 may be located within the display enclosure 10 to facilitate operation of the display device 20 under ambient temperature conditions that fall below the operational range or that would degrade the operation of the display device 20. The heating element 420 may also be operated while the display device 20 is off or in sleep mode, to mitigate damage to the display device 20 that could be caused by ambient temperatures below the storage temperature of the device. Various heating devices and combinations thereof may be used in the display enclosure 10. In a particular embodiment, the heating element 420 comprises one or more electrical strip heaters. Like the internal fan 410, the heating element 420 is electrically coupled to a power source for operation such as the power supply 500. The heating element 420 may have its own control or be electrically coupled to the thermal control unit 510. Where the heating element 420 is coupled to the thermal control unit 510, the thermal control unit 510 activates the heating element 420 upon detecting a temperature within the display enclosure 10 that falls below a second temperature set point. In a particular embodiment, the second temperature set point is set at 5 degrees Celsius. The heating element 420 operates, elevating the temperature within the display enclosure 10, for a predetermined period, until the detected internal temperature rises above the second temperature set point, or the thermal control unit 510 otherwise shuts off the heating element 420.

As noted above, the power supply 500 may be mounted within the display enclosure 10. The power supply 500 is electrically coupled to a power source, for example, directly or indirectly to a conventional power grid or other source. As shown in FIG. 10, an EMI filter 505 may be included between the power source and the power supply 500. The power supply 500 may be used to power devices located within the display enclosure 10 such as, for example, the internal fan 410, the heating element 420, and the thermal control unit 510. The power supply 500 may also be configured to supply power to the display device 20. In addition to the display device 20, the power supply 500 may be a significant heat generator that may raise the internal temperature within the display enclosure 10 during operation. Accordingly, the power supply 500 may include one or more heat sinks operatively coupled to the rear cover assembly 300 to facilitate dissipation of heat generated within the display enclosure 10.

In addition to the devices already described, a display controller 520 that controls the display device 20 may be mounted within display enclosure 10. Alternatively, the display controller 520 may be integral with the display device 20. As shown in FIG. 10, the display controller 520 is electrically coupled to the power supply 500, the display device 20, and the OSD interface 530. The display controller 520 includes inputs for receiving typical audio/visual signals, such as, for example, HDMI, VGA, PC audio input, component video, S-video, composite video, SPDIF, audio inputs, and ATSC/cable tuner. The display controller 520 includes processing components for output of a signal for display by the display device 20. An audio output from the display controller 520 may be directed to the display device 20 or to stand-alone audio equipment that may be situated outside the display enclosure 10. The display controller 520 is also coupled to the OSD accessible from the rear of the display enclosure 10.

The display enclosure 10 may also be provided with an ambient light sensor 540. The ambient light sensor 540 senses the light level outside the display enclosure 10 and may be mounted to the bezel 100 or beneath the front cover 200. The ambient light sensor 540 is electrically coupled to the power supply 500 and the display controller 520. The display controller 520 receives input from the ambient light sensor 540 and, based on the input signal, may be configured to adjust the displayed image, for example, the brightness and/or contrast, generated by the display device 20. For instance, under relatively low ambient light conditions, such as at night when the display enclosure 10 is located outdoors, the display controller 520 may be configured to automatically decrease the brightness of the display device 20 based on the input from the ambient light sensor 540.

The display enclosure 10 may also be provided with features that enable communication between the display device 20 and a remote control device configured to control and the display device 20. The display enclosure 10 may include a remote control input 550. The remote control input 550 comprises an infrared sensor in a particular embodiment. The remote control input 550 is electrically coupled to the display controller 520 and may be mounted to the bezel 100 or located beneath the front cover 200 to receive input from a separate remote control device configured to control the operation of the display device 20.

The construction and arrangements of the display enclosure, as shown in the various exemplary embodiments, are illustrative only. Although only a few embodiments have been described in detail in this disclosure, many modifications are possible (e.g., variations in sizes, dimensions, structures, shapes and proportions of the various elements, values of parameters, orientations, etc.) without materially departing from the novel teachings and advantages of the subject matter described herein. Other substitutions, modifications, changes and omissions may also be made in the design, operating conditions and arrangement of the various exemplary embodiments without departing from the scope of the present invention.

What is claimed is:

1. An enclosure for enclosing a flat panel display, comprising
a bezel defining a perimeter surface defining an enclosure area having a display opening and a rear opening, the bezel including an assembly of a plurality of frame members having beveled ends;
a substantially transparent front cover operatively connected to the bezel and covering the display opening; and
a rear cover assembly operatively connected to the bezel and covering the rear opening,
wherein the bezel, the front cover, and the rear cover assembly define the enclosure configured to receive a flat panel display device therein, and wherein the enclosure is substantially sealed and resistant to liquid ingress.

2. The enclosure of claim 1, wherein the beveled ends of each of the plurality of frame members are configured such that the abutment of the ends of two frame members forms an angle of about ninety degrees between the abutted frame members.

3. The enclosure of claim 1, wherein the bezel comprises an assembly of four frame members, the four frame members oriented so as to form a rectangle.

4. The enclosure of claim 1, wherein the bezel comprises:
a front surface extending inwardly from a front edge of the perimeter surface and defining the display opening; and
a rear surface extending inwardly from a rear edge of the perimeter surface and defining the rear opening.

5. The enclosure of claim 1, wherein the bezel includes a front cover ledge configured for receiving the front cover.

6. The enclosure of claim 1, wherein the beveled ends of each of the plurality of frame members are 45 degrees.

7. The enclosure of claim 1, wherein each of the plurality of frame members is connected to at least one other of the plurality of frame members by a weld.

8. The enclosure of claim 7, wherein each weld is disposed on the perimeter surface of the enclosure.

9. The enclosure of claim 1 further comprising a flat panel display coupled to the bezel and disposed within the enclosure.

10. A method of preparing a substantially sealed enclosure for enclosing a flat panel display device, comprising:
assembling a bezel by joining beveled ends of a plurality of frame members to each other so as to form a rectangle, the bezel characterized by a display opening and a rear opening and having an outer peripheral surface of the enclosure;
attaching a front cover to the bezel, the front cover covering the display opening;
attaching a rear cover to the bezel, the rear cover covering at least a portion of the rear opening; and
placing a flat panel display device within the enclosure through the display opening and coupling the flat panel display device to the bezel, the flat panel display device including a display area viewable through the front cover,
wherein the enclosure is substantially impervious to ingress of liquid.

11. The method of claim 10, wherein the bezel comprises an assembly of four frame members.

12. The method of claim 10, wherein the beveled ends of each of the plurality of frame members are 45 degrees.

13. The method of claim 10, wherein the beveled ends of each of the plurality of frame members are configured such that the abutment of the ends of two frame members forms an angle of about ninety degrees between the abutted frame members.

14. The method of claim 10, wherein the beveled ends of each of the plurality of frame members are joined by welding.

15. The method of claim 10, wherein the weld is made on the outer peripheral surface of the enclosure.

16. The method of claim 10, wherein the weld is ground down so as not to protrude from the outer peripheral surface of the enclosure.

17. An enclosure for enclosing a flat panel display, comprising
a bezel defining a front opening and a rear opening, the bezel comprising a plurality of frame members, each of the plurality of frame members having an outer surface and an inner edge, the outer surface being longer than the inner edge, the plurality of frame members joined to each other at a plurality of mitered joints formed by angled ends at the end of each of the plurality of frame members;
a substantially transparent front cover operatively connected to the bezel and covering the display opening; and
a rear cover assembly operatively connected to the bezel and covering the rear opening,
wherein the bezel, the front cover, and the rear cover assembly define the enclosure configured to receive a flat panel display device therein, and wherein the enclosure is substantially sealed and resistant to liquid ingress.

18. The enclosure of claim 17, wherein the angled ends of each of the plurality of frame members are configured such that the abutment of the ends of two frame members forms an angle of about ninety degrees between the abutted frame members.

19. The enclosure of claim 17, wherein each of the plurality of frame members is connected to at least one other of the plurality of frame members by a weld.

20. The enclosure of claim 19, wherein each weld is disposed on an outer peripheral surface of the enclosure.
